(19) United States
(12) Patent Application Publication
(10) Pub. No.: US 2026/0190362 A1
(43) Pub. Date: Jul. 2, 2026

(54) POWER SEMICONDUCTOR DEVICE

(71) Applicant: Taiwan-Asia Semiconductor Corporation, Hsinchu City (TW)

(72) Inventors: Yueh-Lin Lee, Hsinchu City (TW); De-Lin Hong, Hsinchu City (TW)

(21) Appl. No.: 19/266,717

(22) Filed: Jul. 11, 2025

(30) Foreign Application Priority Data
Dec. 27, 2024 (TW) 113151171

(51) Int. Cl. H10D 8/00

(52) U.S. Cl. CPC H10D 8/825; H10D 8/422

(57) ABSTRACT

A power semiconductor device is provided. The power semiconductor device mainly comprises a first conductive-type highly-doped substrate and a second conductive-type contact region formed thereon. The contact region has a dual-layer doping structure comprising a highly-doped region and a lightly-doped region. Accordingly, the active area of the power device has a five-layer structure of a second conductive-type highly-doped region, a second conductive-type lightly-doped region, an intrinsic semiconductor epitaxial layer, a first conductive-type lightly-doped layer, and a first conductive-type highly-doped substrate, for improving the breakdown voltage of the power device. In addition, metal silicide layers are introduced on the front and back sides of the device and form ohmic contacts with the metal layers thereof to shorten the reverse recovery time (trr) of the device. The metal electrode on the front of the device has a plurality of ring-shaped designs, including at least one second conductive-type metal ring and one first conductive-type metal ring.

### CROSS-REFERENCES TO RELATED APPLICATIONS

This application claims the benefit of priority to Taiwanese Patent Application No. 113151171 filed on Dec. 27, 2024, which is hereby incorporated by reference in its entirety.

### BACKGROUND OF THE INVENTION

### Field of the Invention

This invention relates to a power semiconductor device, and in particular to a fast recovery diode semiconductor device capable of increasing breakdown voltage.

### Descriptions of the Related Art

A fast recovery diode (FRD) is a power semiconductor device used in high-speed switching applications. Under forward bias, an FRD operates like a typical diode, allowing current to pass with a low forward voltage drop, thereby reducing power loss. On the other hand, when switching from forward conduction to reverse blocking, it can quickly remove carriers from the active region, reducing the reverse recovery time (trr), which is critical in high-speed switching applications. Additionally, under reverse bias, the FRD prevents current flow and can withstand a certain reverse voltage without breakdown or failure. Therefore, FRDs are primarily used in switching power supplies, particularly for high-frequency rectification and freewheeling diodes, providing efficient and stable power conversion.

However, with the continuous development of power semiconductor devices, modern power electronics and high-frequency switching circuits increasingly demand fast recovery diodes with shorter reverse recovery times and higher voltage withstand capabilities. In view of this, there is an urgent need in the industry for an innovative power semiconductor device structure to meet the high-performance requirements of next-generation power semiconductor devices.

### SUMMARY OF THE INVENTION

The primary objective of this invention is to provide an innovative power semiconductor device that reduces the reverse recovery time and enhances the voltage withstand capability of the power semiconductor device, thereby improving device performance.

To achieve the above objective, this invention provides a power semiconductor device comprising a substrate, a first conductive-type lightly-doped epitaxial layer, an intrinsic semiconductor epitaxial layer, a central second conductive-type doped region, at least one annular second conductive-type doped region, and an annular first conductive-type doped region. The substrate has a first conductive-type high doping. The first conductive-type lightly-doped epitaxial layer is disposed on the substrate. The intrinsic semiconductor epitaxial layer is disposed on the first conductive-type lightly-doped epitaxial layer. The central second conductive-type doped region is disposed in a central region of the intrinsic semiconductor epitaxial layer. The at least one annular second conductive-type doped region surrounds the central second conductive-type doped region and is disposed spaced apart in a peripheral region of the intrinsic semiconductor epitaxial layer. The annular first conductive-type doped region surrounds the at least one annular second conductive-type doped region and is disposed in the peripheral region of the intrinsic semiconductor epitaxial layer. The central second conductive-type doped region and the at least one annular second conductive-type doped region each comprise a second conductive-type lightly-doped region adjacent to the intrinsic semiconductor epitaxial layer, a second conductive-type highly-doped region encapsulated within the second conductive-type lightly-doped region, and a first metal silicide layer disposed on the second conductive-type highly-doped region.

In one embodiment of the power semiconductor device of this invention, the device further comprises an upper metal layer including a central metal layer, at least one annular metal layer, and an outer annular metal layer. The central metal layer is correspondingly disposed on and electrically connected to the central second conductive-type doped region. The at least one annular metal layer is correspondingly disposed on and electrically connected to the at least one annular second conductive-type doped region. The outer annular metal layer is correspondingly disposed on and electrically connected to the annular first conductive-type doped region.

In one embodiment of the power semiconductor device of this invention, each of the at least one annular metal layer and the outer annular metal layer is one of a rectangular ring, a square ring, an elliptical ring, or a circular ring.

In one embodiment of the power semiconductor device of this invention, the device further comprises a lower metal layer disposed on a backside of the substrate and electrically connected thereto.

In one embodiment of the power semiconductor device of this invention, the device further comprises a second metal silicide layer interposed between the lower metal layer and the substrate.

In one embodiment of the power semiconductor device of this invention, the material of the first metal silicide layer and the second metal silicide layer is selected from the group consisting of platinum silicide (PtSi), nickel silicide (NiSi), titanium silicide (TiSi), chromium silicide (CrSi), palladium silicide (PdSi), molybdenum silicide (MoSi), cobalt silicide (CoSi), tungsten silicide (WSi), and combinations thereof.

In one embodiment of the power semiconductor device of this invention, the thickness of the first metal silicide layer and the second metal silicide layer ranges from 0.01 to 0.5 micrometers (μm).

In one embodiment of the power semiconductor device of this invention, the dopants of the substrate, the first conductive-type lightly-doped epitaxial layer, and the annular first conductive-type doped region are selected from the group consisting of phosphorus (P), arsenic (As), antimony (Sb), bismuth (Bi), and combinations thereof.

In one embodiment of the power semiconductor device of this invention, the dopants of the central second conductive-type doped region and the at least one annular second conductive-type doped region are selected from the group consisting of boron (B), gallium (Ga), indium (In), aluminum (Al), thallium (Tl), and combinations thereof.

In one embodiment of the power semiconductor device of this invention, the doping concentration of the substrate, the annular first conductive-type doped region, and the second conductive-type highly-doped region is greater than 1E17 cm⁻³.

In one embodiment of the power semiconductor device of this invention, the doping concentration of the first conductive-type lightly-doped epitaxial layer and the second conductive-type lightly-doped region ranges from 1E15 to 1E17 cm⁻³.

In one embodiment of the power semiconductor device of this invention, the doping concentration of the intrinsic semiconductor epitaxial layer is less than 1E15 cm⁻³.

In one embodiment of the power semiconductor device of this invention, the first metal silicide layer is further disposed between the annular first conductive-type doped region and the outer annular metal layer.

In one embodiment of the power semiconductor device of this invention, the thickness of the second conductive-type highly-doped region ranges from 0.5 to 5 micrometers (μm), and the thickness of the second conductive-type lightly-doped region ranges from 2 to 10 micrometers (μm).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a partial schematic diagram of a power semiconductor device in one embodiment of this invention;

FIG. 2 is a cross-sectional schematic diagram of a power semiconductor device and a top-view schematic diagram of the upper metal layer in another embodiment of this invention; and

FIG. 3 is a top-view schematic diagram of several embodiments of the upper metal layer of the power semiconductor device of this invention.

### DETAILED DESCRIPTION OF THE PREFERRED EMBODIMENT

In the following description, the present invention will be explained

with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

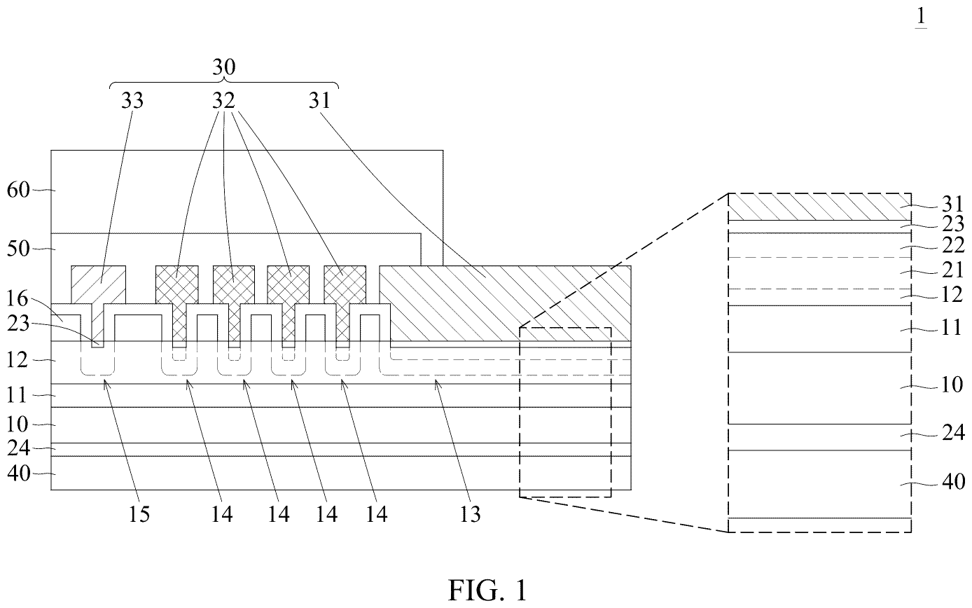

This invention relates to a power semiconductor device, particularly a fast recovery diode semiconductor device capable of rapid switching. Please refer to FIG. 1, which illustrates a partial schematic diagram of a power semiconductor device in one embodiment of this invention. The power semiconductor device 1 includes a substrate 10, which is a silicon substrate with a first conductive-type high doping and a thickness of 100 to 300 micrometers (μm). For example, the substrate 10 is an N-type highly-doped silicon substrate, with dopants selected from the group consisting of phosphorus (P), arsenic (As), antimony (Sb), bismuth (Bi), and combinations thereof, and a doping concentration greater than 1E17 cm⁻³, though not limited thereto.

Next, a first conductive-type lightly-doped epitaxial layer 11 is epitaxially grown on the substrate 10 using Metal Organic Chemical Vapor Deposition (MOCVD) or Molecular Beam Epitaxy (MBE) techniques, with a thickness of 5 to 15 micrometers (μm). This first conductive-type lightly-doped epitaxial layer 11 is an N-type lightly-doped epitaxial layer, with dopants selected from the group consisting of phosphorus (P), arsenic (As), antimony (Sb), bismuth (Bi), and combinations thereof, and a doping concentration ranging from 1E15 to 1E17 cm⁻³, though not limited thereto. Subsequently, an intrinsic semiconductor epitaxial layer 12 is formed on the first conductive-type lightly-doped epitaxial layer 11 by epitaxial growth, with a thickness of 45 to 85 micrometers (μm). In a specific embodiment, the intrinsic semiconductor epitaxial layer 12 has a low level of background dopants, including phosphorus (P) or arsenic (As), with a doping concentration less than 1E15 cm⁻³, though not limited thereto.

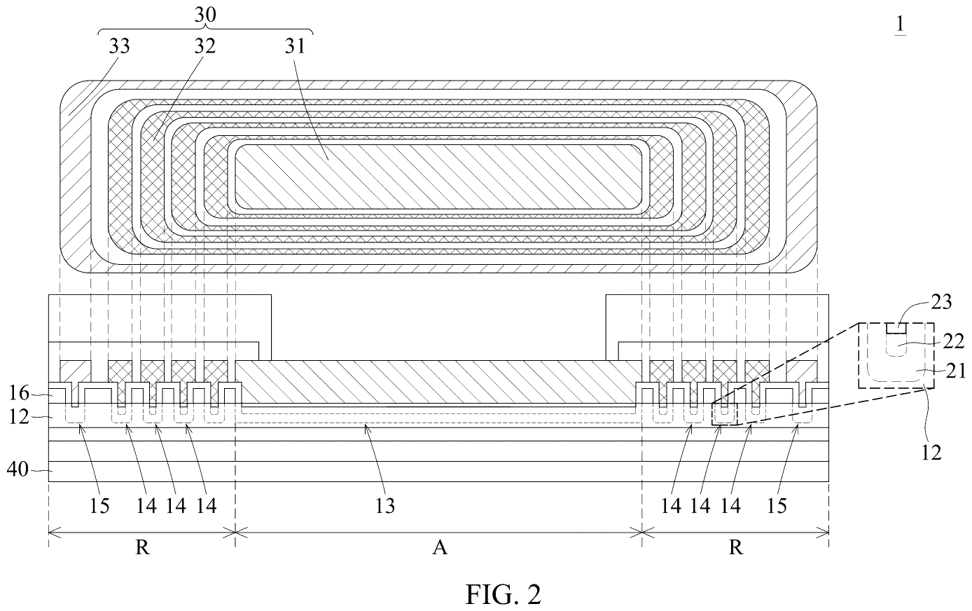

Please refer to both FIG. 1 and FIG. 2, where FIG. 2 illustrates a cross-sectional schematic diagram of a power semiconductor device and a top-view schematic diagram of its upper metal layer in another embodiment of this invention. As shown, the surface of the intrinsic semiconductor epitaxial layer 12 has a patterned oxide layer 16. This oxide layer 16 is formed by patterning and etching a full oxide layer based on the layout of the active region A in the central region of the device and the annular region R in the peripheral regions on both sides of the device, as shown in FIG. 2. Additionally, the doped regions within the semiconductor layers of the substrate are formed by using the patterned oxide layer 16 as a mask and performing multiple ion implantation processes on the substrate. These processes form a central second conductive-type doped region 13 in the active region A, and at least one annular second conductive-type doped region 14 and an annular first conductive-type doped region 15 in the annular region R. It should be noted that the central second conductive-type doped region 13 is disposed in the active region A in the central region of the device. On the other hand, the annular second conductive-type doped region 14 may be a single doped region or multiple doped regions, depending on the device layout design. In the case of multiple doped regions, the annular second conductive-type doped regions 14 are disposed spaced apart in the annular region R, surrounding the central second conductive-type doped region 13. Additionally, the annular first conductive-type doped region 15 is similarly disposed in the outermost peripheral area of the annular region R, surrounding the annular second conductive-type doped region 14.

One feature of this invention is that the central second conductive-type doped region 13, located in the active region A in the central region of the power semiconductor device 1, has a dual-layer doped structure comprising a second conductive-type lightly-doped region 21 and a second conductive-type highly-doped region 22. The second conductive-type lightly-doped region 21 is adjacent to the intrinsic semiconductor epitaxial layer 12 and encapsulates the second conductive-type highly-doped region 22. Specifically, the second conductive-type lightly-doped region 21 is a P-type lightly-doped region with a thickness of 2 to 10 micrometers (μm) and a doping concentration ranging from 1E15 to 1E17 cm⁻³. The second conductive-type highly-doped region 22 is a P-type highly-doped region with a thickness of 0.5 to 5 micrometers (μm) and a doping concentration greater than 1E17 cm⁻³. The dopants in this dual-layer doped structure are selected from the group consisting of boron (B), gallium (Ga), indium (In), aluminum (Al), thallium (Tl), and combinations thereof. In particular, the active region A of the power semiconductor device of this invention has a five-layer structure, including the second conductive-type highly-doped region 22, the second conductive-type lightly-doped region 21, the intrinsic semiconductor epitaxial layer 12, the first conductive-type lightly-doped layer 11, and the first conductive-type highly-doped substrate 10, as shown in the enlarged block outlined by the dashed line in FIG. 1. Within this five-layer structure, the intrinsic semiconductor epitaxial layer 12 has a thickness of 40 to 70 micrometers (μm). This five-layer PN junction structure widens the bandgap between layers, further enhancing the reverse breakdown voltage of the device. Additionally, the depth or thickness of each layer in the aforementioned five-layer structure can be individually adjusted based on the voltage withstand requirements of the power semiconductor device, such as 600 volts (V), 750 volts (V), 850 volts (V), or above 1000 volts (V), and will not be elaborated further.

As shown in FIG. 2, the power semiconductor device 1 of this invention includes multiple annular second conductive-type doped regions 14 in the annular region R on both peripheral sides of the device, with each annular doped region disposed spaced apart from one another. In particular, each annular second conductive-type doped region 14, similar with the central second conductive-type doped region 13, has a dual-layer doped structure, similarly comprising a second conductive-type lightly-doped region 21 and a second conductive-type highly-doped region 22. The second conductive-type lightly-doped region 21 is adjacent to the intrinsic semiconductor epitaxial layer 12 and encapsulates the second conductive-type highly-doped region 22, as shown in the enlarged block outlined by the dashed line in FIG. 2. For details on the dopants and concentrations of each doped region, please refer to the above description, which will not be repeated here. Additionally, the annular region R further includes an annular first conductive-type doped region 15 disposed in the outermost peripheral area of the intrinsic semiconductor epitaxial layer 12 on both sides of the device. Specifically, this annular first conductive-type doped region 15 is an N-type highly-doped region, with dopants selected from the group consisting of phosphorus (P), arsenic (As), antimony (Sb), bismuth (Bi), and combinations thereof, and a doping concentration greater than 1E17 cm⁻³, though not limited thereto.

As shown in FIG. 1 and FIG. 2, the power semiconductor device 1 further includes an upper metal layer 30 comprising a central metal layer 31, at least one annular metal layer 32, and an outer annular metal layer 33. The central metal layer 31 is correspondingly disposed on and electrically connected to the central second conductive-type doped region 13 in the active region A. The at least one annular metal layer 32 is correspondingly disposed on the at least one annular second conductive-type doped region 14 in the annular region R and surrounds the central metal layer 31. The at least one annular metal layer 32 is a second conductive-type metal ring, i.e., a P-type metal ring, and is electrically connected to each annular second conductive-type doped region 14. The outer annular metal layer 33 is correspondingly disposed on the annular first conductive-type doped region 15 in the outermost peripheral area of the annular region R and surrounds the at least one annular metal layer 32. The outer annular metal layer 33 is a first conductive-type metal ring, i.e., an N-type metal ring, and is electrically connected to the annular first conductive-type doped region 15.

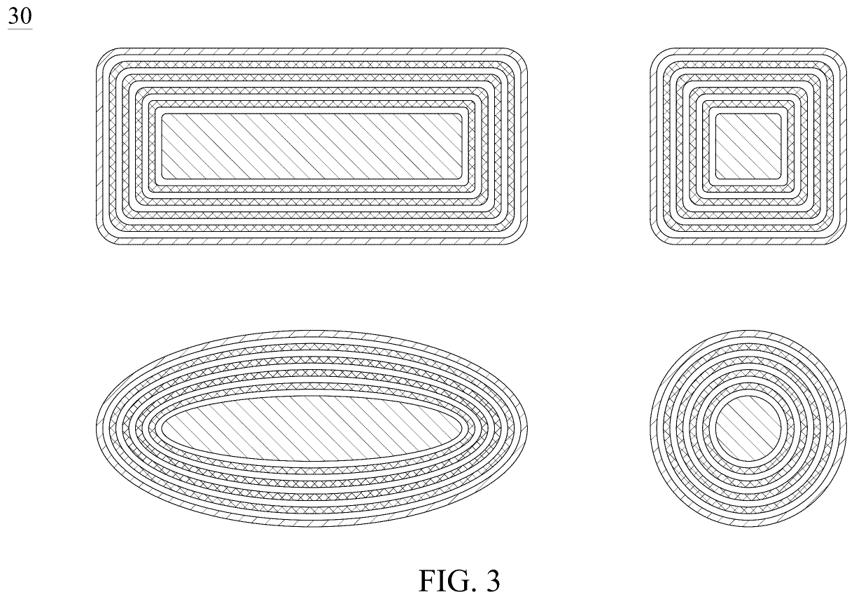

As shown in FIG. 1 and FIG. 2, the intrinsic semiconductor epitaxial layer 12 includes multiple annular second conductive-type doped regions 14. Therefore, the annular metal layer 32 is correspondingly designed as a multi-ring layout, disposed spaced apart, but not limited thereto. In practice, the annular metal layer 32 may also be a single-ring layout, typically comprising 1 to 10 annular designs. Please refer to FIG. 3, where the upper metal layer 30 of the power semiconductor device 1, including the central metal layer 31, the annular metal layer 32, and the outer annular metal layer 33, may be, for example, but not limited to, one of a rectangular ring, a square ring, an elliptical ring, or a circular ring. Additionally, as shown in FIG. 1 and FIG. 2, the power semiconductor device 1 of this invention further includes a passivation layer 50 and a protective layer 60 covering the annular metal layer 32 and the outer annular metal layer 33 in the annular region R.

On the other hand, the power semiconductor device 1 of this invention further includes a lower metal layer 40 disposed on a backside of the substrate 10 and electrically connected thereto. Another feature of this invention is that the power semiconductor device 1 incorporates a metal silicide structure disposed between the upper metal layer 30 and the central second conductive-type doped region 13, the multiple annular second conductive-type doped regions 14, and the annular first conductive-type doped region 15. Specifically, a first metal silicide layer 23 is disposed between the second conductive-type highly-doped region 22 in the central second conductive-type doped region 13 and the multiple annular second conductive-type doped regions 14 and the upper metal layer 30, as well as between the upper metal layer 30 and the annular first conductive-type doped region 15, to form an ohmic contact and thereby reduce the reverse recovery time of the power semiconductor device. Preferably, in another embodiment, the power semiconductor device 1 further includes a second metal silicide layer 24 interposed between the lower metal layer 40 and the substrate 10, as shown in FIG. 1, to further reduce the reverse recovery time of the power semiconductor device. Specifically, the thickness of the aforementioned first metal silicide layer 23 and second metal silicide layer 24 ranges from 0.01 to 0.5 micrometers (μm), and their material is selected from the group consisting of platinum silicide (PtSi), nickel silicide (NiSi), titanium silicide (TiSi), chromium silicide (CrSi), palladium silicide (PdSi), molybdenum silicide (MoSi), cobalt silicide (CoSi), tungsten silicide (WSi), and combinations thereof.

The above embodiments are provided to illustrate the implementations of the present invention and to explain its technical features, and are not intended to limit the scope of the present invention. Any modifications or equivalent arrangements that can be easily accomplished by those skilled in the art fall within the scope of the present invention, and the scope of the present invention should be defined by the claims.

What is claimed is:

1. A power semiconductor device, comprising:
a substrate having a first conductive-type high doping;
a first conductive-type lightly-doped epitaxial layer disposed on the substrate;
an intrinsic semiconductor epitaxial layer disposed on the first conductive-type lightly-doped epitaxial layer;
a central second conductive-type doped region disposed in a central region of the intrinsic semiconductor epitaxial layer;
at least one annular second conductive-type doped region surrounding the central second conductive-type doped region and disposed spaced apart in a peripheral region of the intrinsic semiconductor epitaxial layer; and
an annular first conductive-type doped region surrounding the at least one annular second conductive-type doped region and disposed in the peripheral region of the intrinsic semiconductor epitaxial layer,
wherein the central second conductive-type doped region and the at least one annular second conductive-type doped region comprise:
a second conductive-type lightly-doped region adjacent to the intrinsic semiconductor epitaxial layer;
a second conductive-type highly-doped region encapsulated within the second conductive-type lightly-doped region; and
a first metal silicide layer disposed on the second conductive-type highly-doped region.

2. The power semiconductor device of claim 1, further comprising an upper metal layer including a central metal layer, at least one annular metal layer, and an outer annular metal layer, wherein the central metal layer is correspondingly disposed on and electrically connected to the central second conductive-type doped region, the at least one annular metal layer is correspondingly disposed on and electrically connected to the at least one annular second conductive-type doped region, and the outer annular metal layer is correspondingly disposed on and electrically connected to the annular first conductive-type doped region.

3. The power semiconductor device of claim 2, wherein each of the at least one annular metal layer and the outer annular metal layer is one of a rectangular ring, a square ring, an elliptical ring, or a circular ring.

4. The power semiconductor device of claim 1, further comprising a lower metal layer disposed on a backside of the substrate and electrically connected thereto.

5. The power semiconductor device of claim 4, further comprising a second metal silicide layer interposed between the lower metal layer and the substrate.

6. The power semiconductor device of claim 5, wherein the material of the first metal silicide layer and the second metal silicide layer is selected from the group consisting of platinum silicide (PtSi), nickel silicide (NiSi), titanium silicide (TiSi), chromium silicide (CrSi), palladium silicide (PdSi), molybdenum silicide (MoSi), cobalt silicide (CoSi), tungsten silicide (WSi), and combinations thereof.

7. The power semiconductor device of claim 5, wherein the thickness of the first metal silicide layer and the second metal silicide layer ranges from 0.01 to 0.5 micrometers (μm).

8. The power semiconductor device of claim 1, wherein the dopants of the substrate, the first conductive-type lightly-doped epitaxial layer, and the annular first conductive-type doped region are selected from the group consisting of phosphorus (P), arsenic (As), antimony (Sb), bismuth (Bi), and combinations thereof.

9. The power semiconductor device of claim 1, wherein the dopants of the central second conductive-type doped region and the at least one annular second conductive-type doped region are selected from the group consisting of boron (B), gallium (Ga), indium (In), aluminum (Al), thallium (Tl), and combinations thereof.

10. The power semiconductor device of claim 1, wherein the doping concentration of the substrate, the annular first conductive-type doped region, and the second conductive-type highly-doped region is greater than 1E17 cm⁻³.

11. The power semiconductor device of claim 1, wherein the doping concentration of the first conductive-type lightly-doped epitaxial layer and the second conductive-type lightly-doped region ranges from 1E15 to 1E17 cm⁻³.

12. The power semiconductor device of claim 1, wherein the doping concentration of the intrinsic semiconductor epitaxial layer is less than 1×10¹⁵ cm⁻³.

13. The power semiconductor device of claim 2, wherein the first metal silicide layer is further disposed between the annular first conductive-type doped region and the outer annular metal layer.

14. The power semiconductor device of claim 1, wherein the thickness of the second conductive-type highly-doped region ranges from 0.5 to 5 micrometers (μm), and the thickness of the second conductive-type lightly-doped region ranges from 2 to 10 micrometers (μm).
